(19) United States
(12) Patent Application Publication
(10) Pub. No.: US 2024/0214004 A1
(43) Pub. Date: Jun. 27, 2024

(54) ENCODING/DECODING APPARATUS,ENCODING/DECODING METHOD AND PROGRAM

(71) Applicant: NIPPON TELEGRAPH AND TELEPHONE CORPORATION, Tokyo (JP)

(72) Inventors: Shinobu KUDO, Musashino-shi, Tokyo (JP); Ryuichi TANIDA, Musashino-shi, Tokyo (JP); Hideaki KIMATA, Musashino-shi, Tokyo (JP)

(73) Assignees: NIPPON TELEGRAPH AND TELEPHONE CORPORATION, Tokyo (JP); NIPPON TELEGRAPH AND TELEPHONE CORPORATION, Tokyo (JP)

(21) Appl. No.: 18/286,221

(22) PCT Filed: May 11, 2021
(86) PCT No.: PCT/JP2021/017893

§ 371 Date: Oct. 9, 2023

(51) Int. Cl. H03M 7/30

(52) U.S. Cl. CPC H03M 7/3082; H03M 7/6005; H03M 7/6011

(57) ABSTRACT

An encoding and decoding device includes: an encoding unit configured to convert input data into an encoded feature vector; a quantization accuracy derivation unit configured to derive quantization accuracy for each encoded feature which is an element of the encoded feature vector in accordance with an encoded code amount, a quantization unit configured to generate a quantized encoded feature vector with a size of a quantized code amount which targets the encoded code amount by executing quantization processing on the encoded feature vector based on the quantization accuracy; and a binarization unit configured to generate encoded data by performing binarization processing on the quantized encoded feature vector.

### TECHNICAL FIELD

The present invention relates to an encoding and decoding device, an encoding and decoding method, and a program.

### BACKGROUND ART

A device (an encoding and decoding device) that compresses input data using a machine-learned neural network is known (see NPL 1). FIG. 8 is a diagram illustrating an exemplary configuration of an encoding and decoding device 10. The encoding and decoding device 10 includes an encoding unit 11, a quantization unit 12, a binarization unit 13, and a decoding unit 14 as each functional unit of an autoencoder using a neural network.

The encoding unit 11 converts the input data into vectors (hereinafter referred to as an “encoded feature vector”) that have N (where N is an integer equal to or greater than 1) encoded features as elements. The quantization unit 12 executes quantization processing on the encoded feature vectors based on a vector that has quantization accuracy as an element (hereinafter referred to as a “quantization accuracy vector”). Here, fixed quantization accuracy is determined for each encoded feature (an element of the encoded feature vector).

The binarization unit 13 generates a binarized quantized encoded feature vector (hereinafter referred to as “encoded data”) by binarizing a quantized encoded feature vector (hereinafter referred to as a “quantized encoded feature vector”). The decoding unit 14 generates decoded data by performing decoding processing on the encoded data.

### CITATION LIST

### Non Patent Literature

[NPL 1] Eirikur Agustsson, et al., “Generative Adversarial Networks for Extreme Learned Image Compression,” ICCV2019.

### SUMMARY OF INVENTION

### Technical Problem

An encoding and decoding device generates encoded data with a size of a predetermined code amount. The predetermined code amount is a code amount of a multiplication result of the number of the encoded features “N” and quantization accuracy. However, such an encoding and decoding device has a problem that accuracy with which input data is restored from encoded data cannot be improved.

In view of the foregoing circumstances, an objective of the present invention is to provide an encoding and decoding device, an encoding and decoding method, and a program capable of improving accuracy with which input data is restored from encoded data.

### Solution to Problem

According to an aspect of the present invention, an encoding and decoding device includes: an encoding unit configured to convert input data into an encoded feature vector; a quantization accuracy derivation unit configured to derive quantization accuracy for each encoded feature which is an element of the encoded feature vector in accordance with an encoded code amount, a quantization unit configured to generate a quantized encoded feature vector with a size of a quantized code amount which targets the encoded code amount by executing quantization processing on the encoded feature vector based on the quantization accuracy; a binarization unit configured to generate encoded data by performing binarization processing on the quantized encoded feature vector; and a decoding unit configured to execute decoding processing on predetermined data in accordance with the encoded data.

According to another aspect of the present invention, an encoding and decoding method executed by an encoding and decoding device includes: an encoding step of converting input data into an encoded feature vector; a quantization accuracy derivation step of deriving quantization accuracy for each encoded feature which is an element of the encoded feature vector in accordance with an encoded code amount, a quantization step of generating a quantized encoded feature vector with a size of a quantized code amount which targets the encoded code amount by executing quantization processing on the encoded feature vector based on the quantization accuracy; a binarization step of generating encoded data by performing binarization processing on the quantized encoded feature vector; and a decoding step of executing decoding processing on predetermined data in accordance with the encoded data.

According to an aspect of the present invention, a program causes a computer to function as the foregoing encoding and decoding device.

### Advantageous Effects of Invention

According to the present invention, it is possible to improve accuracy with which input data is restored from encoded data.

### BRIEF DESCRIPTION OF DRAWINGS

FIG. 1 is a diagram illustrating an exemplary configuration of an encoding and decoding device according to a first embodiment.

FIG. 2 is a flowchart illustrating an exemplary operation of the encoding and decoding device according to the first embodiment.

FIG. 3 is a diagram illustrating an exemplary relation between a compression ratio and a peak signal-to-noise ratio according to the first embodiment.

FIG. 4 is a diagram illustrating an example of rate control according to the first embodiment.

FIG. 5 is a diagram illustrating an exemplary configuration of an encoding and decoding device according to a second embodiment.

FIG. 6 is a diagram illustrating an example of scalable decoding according to the second embodiment.

FIG. 7 is a diagram illustrating an exemplary hardware configuration of the encoding and decoding device according to each embodiment.

FIG. 8 is a diagram illustrating an exemplary configuration of an encoding and decoding device.

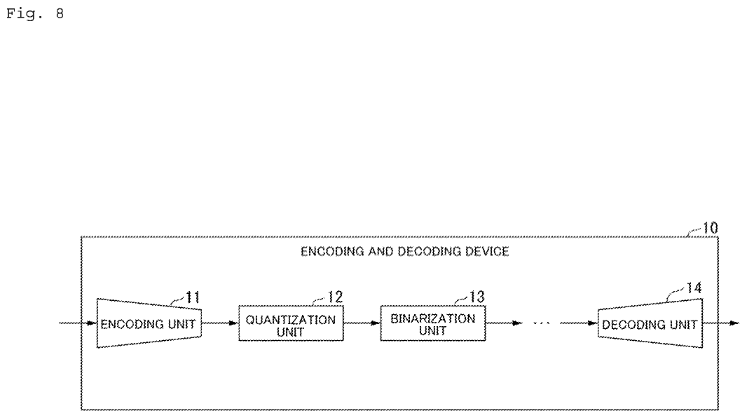

### DESCRIPTION OF EMBODIMENTS

Embodiments of the present invention will be described in detail with reference to the diagrams.

### First Embodiment

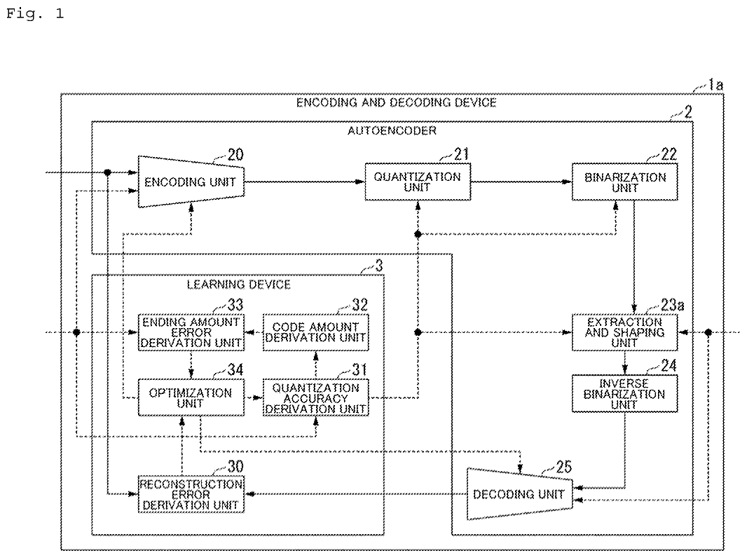

FIG. 1 is a diagram showing an exemplary configuration of the encoding and decoding device 1a. The encoding and decoding device 1a is a system that executes encoding processing (data compression processing) on input data and executes decoding processing on encoded data.

The encoding and decoding device 1a includes an autoencoder 2 and a learning device 3. The autoencoder 2 includes an encoding unit 20, a quantization unit 21, a binarization unit 22, an extraction and shaping unit 23a, an inverse binarization unit 24 and a decoding unit 25. The learning device 3 includes a reconstruction error derivation unit 30, a quantization accuracy derivation unit 31, a code amount derivation unit 32, a code amount error derivation unit 33, and an optimization unit 34.

First, an overview of the autoencoder 2 will be described. The encoding unit 20 has a neural network for executing encoding processing (hereinafter referred to as an “encoding neural network”). The decoding unit 25 has a neural network for executing decoding processing (hereinafter referred to as a “decoding neural network”). The quantization accuracy derivation unit 31 has a neural network for deriving a quantization accuracy vector (hereinafter referred to as a “quantization neural network”). Each of the encoding neural network, the decoding neural network, and the quantization neural network is a neural network to be learned (optimized).

The autoencoder 2 converts the input data into an encoded feature vector by executing encoding processing (data compression processing) using an encoded neural network on the input data.

Hereinafter, an element (quantization accuracy) of a quantization accuracy vector is associated with each element (encoded feature) of the encoded feature vector. The quantization accuracy is adaptively updated by the learning device 3 in accordance with a code amount of one or more encoded features (hereinafter referred to as an “encoded code amount”) (compression rate).

The autoencoder 2 executes quantization processing on the encoded feature vector based on the quantization accuracy vector. The autoencoder 2 converts the encoded feature vector into a quantized encoded feature vector through quantization processing. The autoencoder 2 generates encoded data by performing binarization processing on the quantized encoded feature vector. In the binarization processing, the autoencoder 2 deletes the binary data out of a range of quantization accuracy from the encoded data.

Hereinafter, the code amount of the binary data extracted from the encoded data is referred to as a “decoded code amount.” In the first embodiment, the encoded code amount is equal to the decoded code amount. The autoencoder 2 extracts binary data with the size of the decoded code amount from the encoded data. The autoencoder 2 performs shaping processing on the binary data with the size of the decoded code amount. Here, the autoencoder 2 generates decoded data (shaped decoded data) of the shaped format by shaping the format of the extracted binary data into the format of the quantized encoded feature vector. Here, the autoencoder 2 complements the binary data deleted from the encoded data with a predetermined value (for example, 0) in the decoded data with the shaped format.

The autoencoder 2 generates inverse binarized decoded data by executing inverse binarization processing on the decoded data with the shaped form. The autoencoder 2 generates decoded data by executing decoding processing using the decoding neural network on the inverse binarized decoded data.

Next, details of the autoencoder 2 will be described.

The encoding unit 20 acquires the encoded code amount and the input data from, for example, an information processing device (not illustrated). The encoding unit 20 converts the input data into encoded feature vectors based on the encoded code amount. The quantization unit 21 derives a result of integer rounding processing using a sigmoid function and a quantization accuracy vector for each element of the encoded feature vector as a quantized encoded feature vector with a size of the quantized code amount in which the encoded code amount is targeted. The quantized code amount is a sum of elements in the quantization accuracy vector. The binarization unit 22 generates encoded data by executing binarization processing on the quantized encoded feature vector based on the quantization accuracy vector. Here, the binarization unit 22 generates encoded data by deleting the binary data out of the range of the quantization accuracy from the quantization accuracy vector.

The extraction and shaping unit 23a extracts binary data with the size of the decoded code amount from the acquired encoded data. The extraction and shaping unit 23a shapes the format of the binary data extracted from the acquired encoded data into the format of the quantized encoded feature vector based on the quantization accuracy vector. Here, the extraction and shaping unit 23a complements the binary data out of the range of quantization accuracy with a predetermined value based on the quantization accuracy in the decoded data. Accordingly, the extraction and shaping unit 23a generates decoded data with a shaped format.

The inverse binarization unit 24 generates inverse binary decoded data by executing inverse binarization processing on the decoded data with the shaped format. The decoding unit 25 executes decoding processing on the inverse binary decoded data based on the decoded code amount. Thus, the decoding unit 25 converts the inverse binary decoded data into the decoded data.

Next, an overview of the learning device 3 will be described. The learning device 3 is a device that executes learning processing (machine learning). The learning device 3 derives a difference between the input data and the decoded data (an inter-vector distance). The difference between the input data and the decoded data is expressed by using, for example, a mean square error. The learning device 3 derives a difference between a quantized code amount which is a sum of elements in the quantization accuracy vectors and the encoding code amount (compression rate). The learning device 3 generates an objective function based on each difference.

The learning device 3 updates at least one of a parameter of the encoding neural network of the encoding unit 20, a parameter of the decoding neural network of the decoding unit 25, and a parameter of the quantization neural network of the quantization accuracy derivation unit 31 so that a difference between the input data and the decoded data becomes small (a value of the objective function becomes small). In this way, the learning device 3 adaptively updates the element (quantization accuracy) of the quantization accuracy vector in accordance with the encoded code amount.

The learning device 3 (optimization device) outputs the updated parameter of the encoding neural network to the encoding unit 20. The learning device 3 outputs the updated parameter of the decoding neural network the decoding unit 25. The learning device 3 outputs the updated parameter of the quantization neural network to the quantization accuracy derivation unit 31.

Next, details of the first communication device 3 will be described.

The reconstruction error derivation unit 30 derives a reconstruction error that is an error of decoded data with respect to the input data. The quantization accuracy derivation unit 31 derives a quantization accuracy vector in accordance with the encoded code amount. Here, the quantization accuracy derivation unit 31 derives a quantization accuracy vector using the quantization neural network on the encoded code amount. The parameter of the quantization neural network is updated by the optimization unit 34.

The code amount derivation unit 32 derives a quantized code amount [bit] which is a sum of “N” elements in the quantization accuracy vector. The code amount error derivation unit 33 derives a code amount error (a difference between the encoded code amount and the quantized code amount) which is an error of the quantized code amount with respect to the encoded code amount.

The optimization unit 34 derives an objective function based on the reconfiguration error and the code amount error. The optimization unit 34 performs optimization processing on the objective function. The optimization unit 34 updates at least one of the parameter of the encoding neural network of the encoding unit 20, the parameter of the decoding neural network of the decoding unit 25, and the parameter of the quantization neural network of the quantization accuracy derivation unit 31 by executing, for example, an error inverse propagation method on the minimized objective function.

Next, an exemplary operation of the encoding and decoding device 1a will be described.

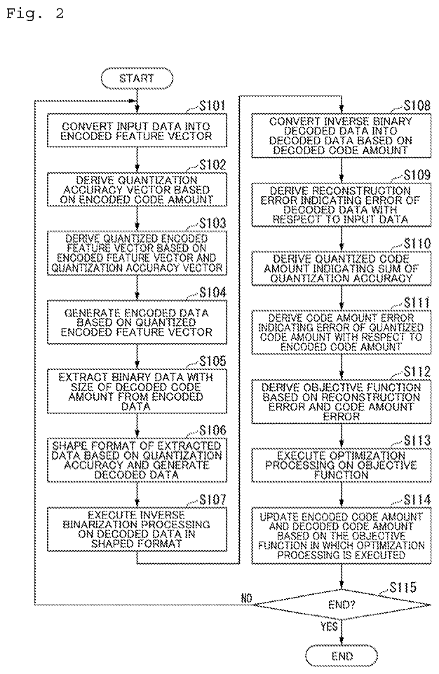

FIG. 2 is a flowchart illustrating an exemplary operation of the encoding and decoding device 1a. The encoding unit 20 acquires an encoded code amount “R_{enc}” and input data “x” from, for example, an information processing device (not illustrated). The encoding unit 20 converts the input data “x” into an encoded feature vector “z=[z₁, . . . , z_{N}].” The value of the encoded feature “zₙ” indicates a feature amount of an encoding object (step S101).

The quantization accuracy derivation unit 31 acquires the encoded code amount “R_{enc}” from, for example, an information processing device (not illustrated). The quantization accuracy derivation unit 31 derives a quantization accuracy vector “B=[B₁, . . . , B_{N}]”” using a quantization neural network on the encoded code amount “R_{enc}.” Here, a value of the element “Bₙ” of the quantization accuracy vector is, for example, an integer equal t or greater than 0 and equal to or less than 64 (step S102).

In this way, the value of the element “Bₙ” may be 0. The quantization accuracy derivation unit 31 controls the number of the quantized encoded features “N” included in the encoded data by changing the quantization accuracy in accordance with the encoded code amount.

The quantization unit 21 acquires the encoded feature vector “z” from the encoding unit 20. The quantization unit 21 acquires the quantization accuracy vector “B” from the quantization accuracy derivation unit 31. The quantization unit 21 derives a result “zₙ^{q}=Q (sigmoid (zₙ) (2^{Bn}-1))” of integer rounding processing “Q” using a sigmoid function “sigmoid (zₙ)” and the quantization accuracy vector “B” as a quantized encoded feature vector “z^{q}=[z₁^{q}, . . . , zₙ^{q}]” with a size of a quantized code amount targeting the encoded code amount, for each element “zₙ” of the encoded feature vector (step S103).

The binarization unit 22 acquires the quantized encoded feature vector “z^{q}” from the quantization unit 21. The binarization unit 22 acquires the quantization accuracy vector from the quantization accuracy derivation unit 31. The binarization unit 22 generates encoded data “z^{enc}” by executing binarization processing on the quantized encoded feature vector based on the quantization accuracy vector. Here, the binarization unit 22 deletes the binary data out of the range of the quantization accuracy from the encoded data “z^{enc}”. (step S104).

The extraction and shaping unit 23a acquires a decoded code amount “R_{dec}” from, for example, an information processing device (not illustrated). The extraction and shaping unit 23a acquires the encoded data “z^{enc}” from the binarization unit 22. The extraction and shaping unit 23a extracts binary data with the size of the decoded code amount “R_{dec}” from the acquired encoded data “z^{enc}” (step S105).

The extraction and shaping unit 23a acquires the quantization accuracy vector “B” from the quantization accuracy derivation unit 31. The extraction and shaping unit 23a shapes the format of the binary data extracted from the acquired encoded data “z^{enc}” into the format of the quantized encoded feature vector “z^{q}” based on the quantization accuracy vector “B.” Here, the extraction and shaping unit 23a complements binary data out of the range of the quantization accuracy with a predetermined value (for example, 0) in the decoded data. Accordingly, the extraction and shaping unit 23a generates decoded data “z^{dec}” in a shaped format (step S106).

Hereinafter, symbols added above characters in expressions are written immediately before the characters. For example, a symbol “\hat{ }” added above character “z^{q}” in an expression is written immediately before character “z^{q}” such as “\hat{ }z^{q}.”

The inverse binarization unit 24 generates inverse binary decoded data “\hat{ }z^{q}” by executing inverse binarization processing on the decoded data “z^{dec}” in the shaped format (step S107). The decoding unit 25 executes decoding processing on the inverse binary decoded data “\hat{ }z^{q}” based on the decoded code amount “R_{dec}.” Accordingly, the decoding unit 25 converts the inverse binary decoded data “\hat{ }z^{q}” into decoded data “\hat{°}x” (step S108).

The reconstruction error derivation unit 30 acquires input data from, for example, an information processing device (not illustrated). The reconstruction error derivation unit 30 acquires decoded data (reconstruction data) from the decoding unit 25. The reconstruction error derivation unit 30 derives a reconstruction error “L_{rec}=d (x, \hat{ }x)” which is an error of the decoded data “\hat{ }x” with respect to the input data “x.” The function “d” is any function of deriving an inter-vector distance, for example, a sum of mean square errors or a binary cross entropy (step S109).

The code amount derivation unit 32 acquires the quantization accuracy vector “B” from the quantization accuracy derivation unit 31. The code amount derivation unit 32 derives a quantized code amount “R=ΣBₙ” [bit] which is a sum of “N” elements “Bₙ” in the quantization accuracy vector (step S110).

The code amount error derivation unit 33 acquires an encoded code amount “R_{enc}.” The code amount error derivation unit 33 acquires the quantized code amount “R=ΣBₙ” from the quantization accuracy derivation unit 31. The code amount error derivation unit 33 derives a code amount error “Lᵣₐₜₑ=d(R_{enc}, R)” which is an error of the quantized code amount “R=ΣBₙ” with respect to the encoded code amount “R_{enc}” (step S111).

The optimization unit 34 derives an objective function “L=L_{rec}+λLᵣₐₜₑ” based on the reconfiguration error “L_{rec}” and the code amount error “Lᵣₐₜₑ.” The weight “λ” is any value (step S112).

The optimization unit 34 executes optimization processing on the objective function “L.” That is, the optimization unit 34 solves a minimization problem of the objective function “L” by executing, for example, a gradient method (step S113).

The optimization unit 34 updates at least one of the parameter of the encoding neural network of the encoding unit 20, the parameter of the decoding neural network of the decoding unit 25, and the parameter of the quantization neural network of the quantization accuracy derivation unit 31 by executing, for example, an error inverse propagation method on the minimized objective function “L.”

The optimization unit 34 outputs the updated parameter of the encoding neural network to the encoding unit 20. The optimization unit 34 outputs the updated parameter of the quantization neural network to the quantization accuracy derivation unit 31. The optimization unit 34 outputs the updated parameter of the decoding neural network to the decoding unit 25 (step S114).

The optimization unit 34 determines whether the processing illustrated in FIG. 2 ends based on a predetermined condition. For example, the optimization unit 34 ends the processing when the predetermined condition that the processing shown in FIG. 2 is executed a predetermined number of times or more is satisfied. For example, when the predetermined condition that the value of the objective function “L” is equal to or less than a predetermined value is satisfied, the optimization unit 34 ends the processing (step S115).

When it is determined that the processing continues (No in step S115), the optimization unit 34 returns the processing to step S101. When it is determined that the processing ends (Yes in step S115), the optimization unit 34 ends the processing illustrated in FIG. 2.

As described above, the encoding unit 20 converts the input data into the encoded feature vector. The quantization accuracy derivation unit 31 derives quantization accuracy for each encoded feature which is an element of the encoded feature vector in accordance with the encoded code amount. The quantization unit 21 generates a quantized encoded feature vector with a size of a quantized code amount targeting the encoded code amount by executing quantization processing on the encoded feature vector based on the quantization accuracy. The binarization unit 22 generates encoded data by executing binarization processing on the quantized encoded feature vector. The decoding unit 25 executes the decoding processing on predetermined data corresponding to the encoded data.

The extraction and shaping unit 23a extracts binary data with the size of the decoded code amount from the encoded data. The extraction and shaping unit 23a generates shaped decoded data by shaping the format of the extracted binary data based on quantization accuracy. The inverse binarization unit 24 generates inverse binary decoded data by executing inverse binarization processing on the shaped decoded data. The decoding unit 25 converts the inverse binary decoded data into decoded data by executing decoding processing on the inverse binary decoded data (predetermined data) based on the decoded code amount.

The optimization unit 34 updates at least one of a parameter used for encoding processing for converting input data into an encoded feature vector, a parameter used for decoding processing, and a parameter used for deriving quantization accuracy based on the objective function.

In this way, the number of encoded features “N” and the quantization accuracy “Bₙ” are not fixed, and the quantization accuracy “Bₙ” is derived in accordance with the encoded code amount (compression ratio). Since the number of encoded features “N” is determined in accordance with the quantization accuracy “Bₙ,” the input data is encoded with an optimum expression (a combination of the number of encoded features and the quantization accuracy) corresponding to the encoded code amount. Accordingly, it is possible to improve restoration accuracy at which the input data is restored from the encoded data.

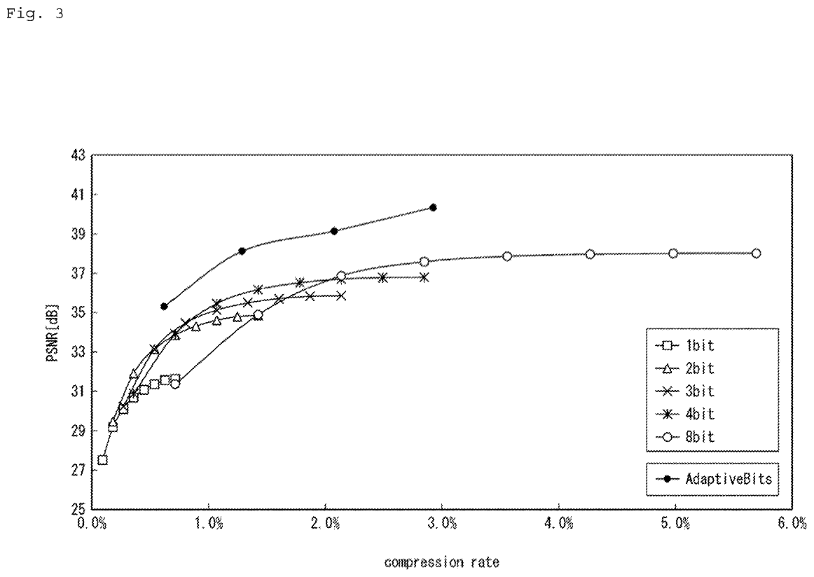

FIG. 3 is a diagram illustrating an exemplary relation between the compression ratio (code amount) and the peak signal-to-noise ratio. FIG. 3 illustrates an exemplary relation between the compression ratio and the peak signal-to-noise ratio of the seismic wave data. The horizontal axis represents compression rate. The vertical axis represents a peak signal-to-noise ratio (PSNR) [dB].

“1 bit”, “2 bit,” “3 bit,” “4 bit,” and “8 bit” illustrated in FIG. 3 indicate each fixed quantization accuracy. Each graph of “1 bit”, “2 bit,” “3 bit,” “4 bit,” and “8 bit” is a graph related to an autoencoder of the related art. In each graph of the autoencoder of the related art, quantization accuracy associated with the encoded feature is uniformly X [bit] for all the encoded features. In each graph related to the autoencoder of the related art, points are plotted for each number of encoded features.

On the other hand, “AdaptiveBits” illustrated in FIG. 3 indicates adaptively changed quantization accuracy (quantization accuracy corresponding to the encoded code amount). The graph of “AdaptiveBits” is a graph related to the encoding and decoding device 1a. In the graph related to the encoding and decoding device 1a, points are plotted for each encoded code amount. Thus, the encoding and decoding device 1a can improve the accuracy (peak signal-to-noise ratio) at which the input data is restored from the encoded data.

Next, details of the binarization unit 22 and the extraction and shaping unit 23a will be described.

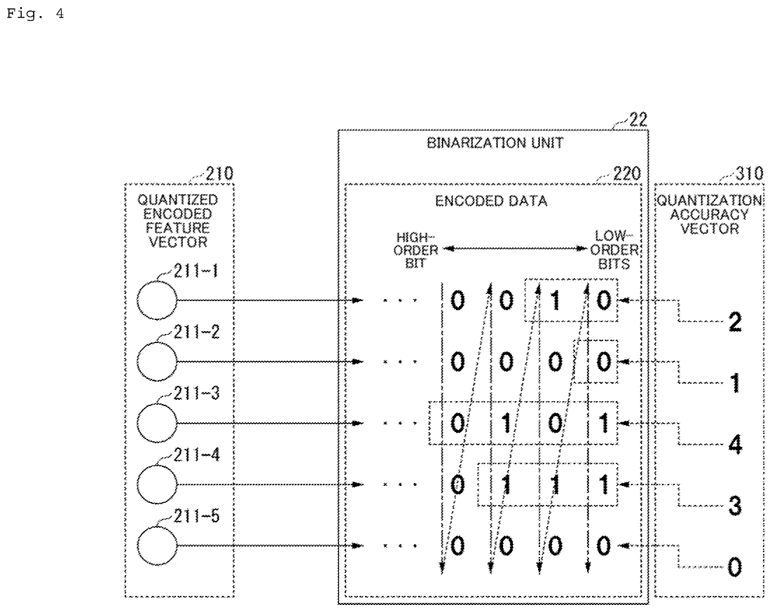

FIG. 4 is a diagram illustrating an example of rate control. In FIG. 4, a quantized encoded feature vector 210 includes, as an example, quantization encoded features from elements 211-1 to 211-5.

The binarization unit 22 acquires the quantized encoded feature vector 210 from the quantization unit 21. The binarization unit 22 generates encoded data 220 including the binary data by executing binarization processing on the quantized encoded feature vector 210.

The binarization unit 22 acquires a quantization accuracy vector 310 from a quantization accuracy derivation unit 31. In FIG. 4, the quantization accuracy vector 310 is “[2, 1, 4, 3, 0]” as an example. The binarization unit 22 acquires the encoded data 220 including the binary data of each element 211 from the binarization unit 22.

The quantization accuracy associated with the binary data “ . . . 0010” of the element 211-1 is “2” in the quantization accuracy vector 310. The quantization accuracy associated with the binary data “ . . . 0000” of the element 211-2 is “1” in the quantization accuracy vector 310. The quantization accuracy associated with the binary data “ . . . 0101” of the element 211-3 is “4” in the quantization accuracy vector 310. The quantization accuracy associated with the binary data “ . . . 0111” of the element 211-4 is “3” in the quantization accuracy vector 310. The quantization accuracy associated with the binary data “ . . . 0000” of the element 211-5 is “0” in the quantization accuracy vector 310.

The binarization unit 22 deletes the binary data out of the range of the quantization accuracy (out of a rectangular frame indicated by a dotted line in FIG. 4) from the encoded data 220. Thus, the binarization unit 22 generates the encoded data 220 with the size of the quantized code amount designated using the quantization accuracy vector 310.

Here, the binarization unit 22 scans the binary data of all the elements 211. The binarization unit 22 scans the binary data of all the elements 211 in order from high-order bits to low-order bits of the binary data. The binarization unit 22 scans the binary data of all the elements 211, for example, in order from the element 211-1 to the element 211-5. Each arrow of the one-dot chain line shown in the encoded data 220 in FIG. 4 indicates order of the scanning.

By scanning the binary data in order from the element 211-1 to the element 211-5, the binarization unit 22 acquires “0” of the most significant bit within the range of each quantization accuracy from the binary data. The binarization unit 22 acquires “1” and “1” of high-order bits of the lower side within the range of each quantization accuracy from the binary data. The binarization unit 22 acquires “1,” “0,” and “1” of the high-order bits of the further lower side within the range of each quantization accuracy from the binary data. The binarization unit 22 acquires “0,” “0,” “1,” and “1” of the least-significant bit within the range of each quantization accuracy from the binary data.

In FIG. 4, the quantization accuracy associated with the binary data “ . . . 0000” of the element 211-5 is “0.” Therefore, the binary data of the element 211-5 is out of the range of quantization accuracy. Therefore, in the scanning, the binarization unit 22 does not acquire the binary data “ . . . 0000” of the element 211-5. In this way, the binarization unit 22 deletes the binary data “ . . . 0000” of the element 211-5 of which quantization accuracy is “0” from the encoded data 220.

The binarization unit 22 generates rate-controlled encoded data 220 by combining the acquired binary data (“0,” “11,” “101,” “0011”) in the acquisition order of the binary data. In FIG. 4, the rate-controlled encoded data 220 is “0111010011.”

The binary data out of the range of quantization accuracy among the binary data of the encoded feature is deleted from the encoded data as rate control. In FIG. 4, only the binary data in each rectangular frame indicated by a dotted line is transmitted as the encoded data 220 to the extraction and shaping unit 23a.

The extraction and shaping unit 23a acquires the encoded data 220 from the binarization unit 22. The extraction and shaping unit 23a acquires the quantization accuracy vector 310 from the quantization accuracy derivation unit 31. The extraction and shaping unit 23a extracts binary data with the size of the decoded code amount from the encoded data 220.

The extraction and shaping unit 23a performs shaping processing on the binary data extracted from the rate-controlled encoded data 220. Here, the extraction and shaping unit 23a generates decoded data (shaped decoded data) with the shaped format by shaping the format of the extracted binary data into the format of the quantized encoded feature vector.

The extraction and shaping unit 23a specifies the position of the binary data deleted from the rate-controlled encoded data 220 using the quantization accuracy vector 310. The extraction and shaping unit 23a complements the binary data deleted from the rate-controlled encoded data 220 with a predetermined value (for example, 0) in the decoded data with the shaped format.

As described above, the binarization unit 22 deletes the binary data out of the range of the quantization accuracy from the encoded data 220 based on the quantization accuracy vector 310. The extraction and shaping unit 23a specifies a bit position of the binary data deleted from the encoded data 220 based on the quantization accuracy. The extraction and shaping unit 23a complements the position of the binary data deleted from the encoded data 220 with a predetermined value (for example, 0) in the shaped decoded data.

In this way, it is possible to improve the accuracy at which the input data is restored from the encoded data. Even if an encoding and decoding device 1b is not prepared for each encoded code amount (compression rate), the encoding and decoding device 1b can execute rate control.

### Second Embodiment

In the second embodiment, a difference from the first embodiment is that the coding and decoding device executes scalable decoding. The scalable decoding is processing for decoding decoded data (reconstructed data of input data) of any code amount equal to or less than the encoded code amount from the encoded data. In the second embodiment, differences with the first embodiment will be mainly described.

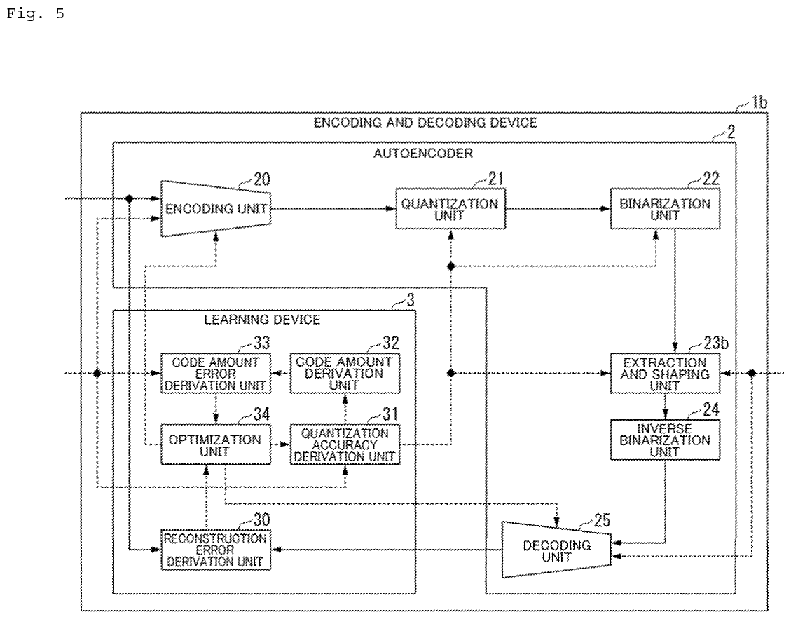

FIG. 5 is a diagram illustrating an exemplary configuration of the encoding and decoding device 1b. The encoding and decoding device 1b is a system that executes encoding processing (data compression processing) on input data and executes decoding processing to encoded data. In the decoding processing, the encoding and decoding device 1b executes the scalable decoding on the decoded data extracted from the encoded data.

The encoding and decoding device 1b includes an autoencoder 2 and a learning device 3. The autoencoder 2 includes an encoding unit 20, a quantization unit 21, a binarization unit 22, an extraction and shaping unit 23b, an inverse binarization unit 24, and a decoding unit 25. The learning device 3 includes a reconstruction error derivation unit 30, a quantization accuracy derivation unit 31, a code amount derivation unit 32, a code amount error derivation unit 33, and an optimization unit 34.

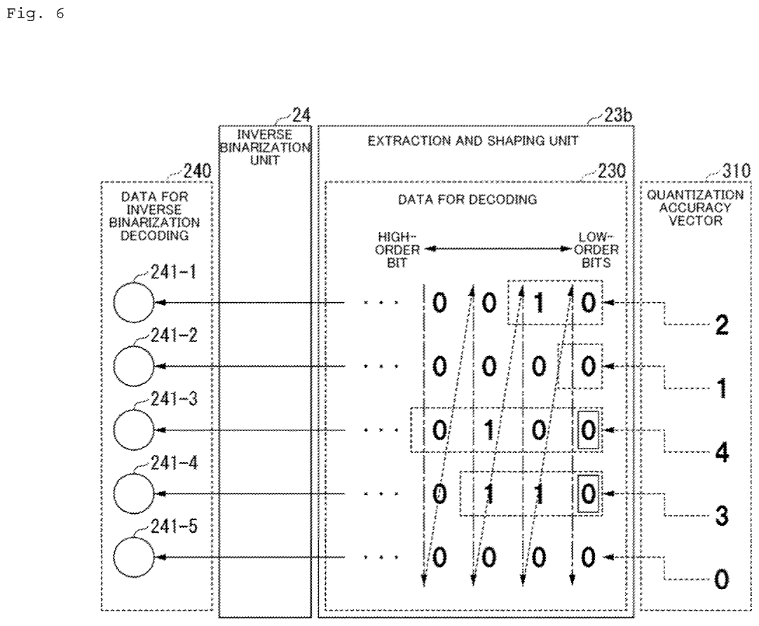

FIG. 6 is a diagram illustrating an example of scalable decoding. The extraction and shaping unit 23b acquires a quantization accuracy vector 310 from the quantization accuracy derivation unit 31. In FIG. 6, the quantization accuracy vector 310 is, for example, “[2, 1, 4, 3, 0].” That is, in this example, the quantized code amount “R”=10 bits is set.

The extraction and shaping unit 23b acquires a decoded code amount “R_{dec}” from, for example, an information processing device (not illustrated). In the second embodiment, the decoded code amount “R_{dec}” is equal to or less than the quantized code amount “R.” The extraction and shaping unit 23b acquires the encoded data 220 from the binarization unit 22. The extraction and shaping unit 23b extracts binary data with the size of the decoded code amount designated by using the quantization accuracy vector 310 from the encoded data 220.

The extraction and shaping unit 23b performs shaping processing on the binary data extracted from the encoded data 220. Here, the extraction and shaping unit 23b generates decoded data 230 of the shaped format by shaping the format of the extracted binary data into the format of the quantized encoded feature vector.

In FIG. 6, the inverse binary decoded data 240 includes, for example, inverse binary data from elements 241-1 to 241-5.

The quantization accuracy associated with the binary data “ . . . 0010” of the element 241-1 is “2” in the quantization accuracy vector 310. The quantization accuracy associated with the binary data “ . . . 0000” of the element 241-2 is “1” in the quantization accuracy vector 310. The quantization accuracy associated with the binary data “ . . . 0101” (in scalable decoding, “ . . . 0100”) of the element 241-3 is “4” in the quantization accuracy vector 310. The quantization accuracy associated with the binary data “ . . . 0111” (in scalable decoding, “ . . . 0110”) of the element 241-4 is “3” in the quantization accuracy vector 310. The quantization accuracy associated with the binary data “ . . . 0000” of the element 241-5 is “0” in the quantization accuracy vector 310.

The extraction and shaping unit 23b deletes binary data out of the range of quantization accuracy (out of a rectangular frame indicated by a dotted line in FIG. 6) from decoded data 230 in a shaped form. Thus, the extraction and shaping unit 23b generates the decoded data 230 with the size of the decoded code amount designated using the quantization accuracy vector 310.

Here, the extraction and shaping unit 23b scans the binary data of all the elements 241. The extraction and shaping unit 23b scans the binary data of all the elements 241 in order from the high-order bits to the low-order bits of the binary data. Also, the extraction and shaping unit 23b scans the binary data of all the elements 241, for example, in order from the element 241-1 to the element 241-5. Each arrow of the one-dot chain line shown in the decoded data 230 in FIG. 6 indicates an order of such scanning. The extraction and shaping unit 23b acquires elements corresponding to the size of the decoded code amount “R_{dec}.” The extraction and shaping unit 23b sets the remaining elements which have not been acquired to a predetermined value (for example, 0).

In the second embodiment, the decoded code amount “R_{dec}” is, for example, 8 bits. By performing the scanning in order from the element 241-1 to the element 241-5, the extraction and shaping unit 23b acquires “0” of the most significant bit within the range of each quantization accuracy from the binary data. The extraction and shaping unit 23b acquires “1” and “1” of the high-order bits of the lower side within the range of each quantization accuracy from the binary data. The extraction and shaping unit 23b acquires “1,” “0,” and “1” of the high-order bits of the further lower side within the range of each quantization accuracy from the binary data. The extraction and shaping unit 23b acquires “0” and “0” of the least-significant bit within the range of each quantization accuracy from the binary data. At this time, 8-bit binary data of the decoded code amount “R_{dec}” is extracted. Therefore, the extraction and shaping unit 23b does not acquire the remaining binary data within the range of quantization accuracy and sets the data to a predetermined value (for example, 0). In FIG. 6, the extraction and shaping unit 23b sets each value “1” of the remaining binary data within the range of quantization accuracy to each value “0” so that each value is surrounded by a rectangle indicated by a solid line in FIG. 6.

In FIG. 6, the quantization accuracy associated with the binary data “ . . . 0000” of the element 241-5 is “0.” Therefore, the binary data of the element 241-5 is out of the range of quantization accuracy. Therefore, in the scanning, the extraction and shaping unit 23b does not acquire the binary data “ . . . 0000” of the element 241-5. Thus, the extraction and shaping unit 23b deletes the binary data “ . . . 0000” of the element 241-5 of which quantization accuracy is “0” from the decoded data 230.

The extraction and shaping unit 23b generates decoded data 230 with the size of the decoded code amount designated using the quantization accuracy vector 310 by combining the acquired binary data (“0,” “11,” “101,” “0000”) in the acquisition order of the binary data. In FIG. 6, the decoded data 230 with the size of the decoded code amount is “0111010000.” In this way, only the binary data in each rectangular frame indicated by the dotted line in FIG. 6 is transmitted to the inverse binarization unit 24 as the decoded data 230 with the size of the decoded code amount.

The inverse binarization unit 24 acquires the decoded data 230 with the size of the decoded code amount from the extraction and shaping unit 23b. The inverse binarization unit 24 generates inverse binary decoded data 240 by executing inverse binarization processing on the decoded data 230 with the size of the decoded code amount.

As described above, the extraction and shaping unit 23b acquires the binary data within the range of quantization accuracy from the extracted binary data. The extraction and shaping unit 23b generates the decoded data 230 (shaped decoded data) in the shaped format by shaping the format of the binary data within the range of quantization accuracy. Here, the extraction and shaping unit 23b generates the decoded data 230 in the shaped form by extracting the binary data with the size of the decoded code amount from the binary data within the range of quantization accuracy.

Accordingly, it is possible to improve the accuracy at which the input data is restored from the encoded data. Even if the encoding and decoding device 1b is not prepared for each encoded code amount (compression rate), the encoding and decoding device 1b can execute the scalable decoding.

### Example of Hardware Configuration

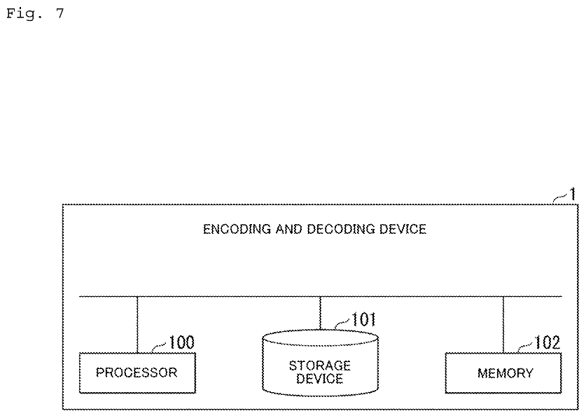

FIG. 7 is a diagram illustrating an exemplary hardware configuration of the encoding and decoding device 1 (an encoding device) (a decoding device) (a data compression device) according to the embodiment. The encoding and decoding device 1 corresponds to each of the foregoing encoding and decoding device 1a and the foregoing encoding and decoding device 1b. Some or all of the functional units of the encoding and decoding device 1 are implemented as software when a processor 100 such as a central processing unit (CPU) executes a program stored in a storage device 101 and a memory 102 that includes a nonvolatile recording medium (a non-transitory recording medium). The program may be recorded on a computer-readable recording medium. The computer-readable recording medium is, for example, or a non-temporary recording medium such as a portable medium such as a flexible disk, a magneto-optical disc, a read only memory (ROM) or a compact disc read only memory (CD-ROM), a storage device such as a hard disk built in a computer system.

Some or all of the functional units of the encoding and decoding device 1 may be implemented using hardware including, for example, an electronic circuit or circuitry in which a large scale integrated circuit (LSI), an application specific integrated circuit (ASIC), a programmable logic device (PLD), a field programmable gate array (FPGA), or the like is used.

Although the embodiments of the present invention have been described in detail with reference to the drawings, specific configurations are not limited to these embodiments, and design and the like within the scope of the gist of the present invention are also included.

### INDUSTRIAL APPLICABILITY

The present invention can be applied to a device that executes predetermined data processing.

### REFERENCE SIGNS LIST

1a, 1b Encoding and decoding device
10 Encoding and decoding device
11 Encoding unit
12 Quantization unit
13 Binarization unit
14 Decoding unit
20 Encoding unit
21 Quantization unit
22 Binarization unit
23a, 23b Extraction and shaping unit
24 Inverse binarization unit
25 Decoding unit
30 Reconstruction error derivation unit
31 Quantization accuracy derivation unit
32 Code amount derivation unit
33 Encoding error derivation unit
34 Optimization unit
100 Processor
101 Storage device
102 Memory
210 Quantized encoded feature vector
211 Elements
220 Encoded data
230 Decoded data
240 Inverse binary decoded data
241 Element
310 Quantization accuracy vector

1. An encoding and decoding device comprising:
an encoding unit configured to convert input data into an encoded feature vector;
a quantization accuracy derivation unit configured to derive quantization accuracy for each encoded feature which is an element of the encoded feature vector in accordance with an encoded code amount,
a quantization unit configured to generate a quantized encoded feature vector with a size of a quantized code amount which targets the encoded code amount by executing quantization processing on the encoded feature vector based on the quantization accuracy;
a binarization unit configured to generate encoded data by performing binarization processing on the quantized encoded feature vector; and
a decoding unit configured to execute decoding processing on predetermined data in accordance with the encoded data.

2. The encoding and decoding device according to claim 1, further comprising:
an extraction and shaping unit configured to generate shaped decoded data by extracting binary data with a size of a decoded code amount from the encoded data and shaping a format of the extracted binary data into a format of the quantized encoded feature vector based on the quantization accuracy; and
an inverse binarization unit configured to generate inverse binary decoded data by executing inverse binarization processing on the shaped decoded data, wherein the decoding unit converts the inverse binary decoded data into decoded data by executing the decoding processing on the inverse binary decoded data based on the decoded code amount.

3. The encoding and decoding device according to claim 2, further comprising:
a reconstruction error derivation unit configured to derive a reconstruction error which is an error of the decoded data with respect to the input data; and
an optimization unit configured to derive a code amount error which is a difference between the encoded code amount and the quantized code amount which is a sum of the quantization accuracy, derive an objective function based on the reconstruction error and the code amount error, and update at least one of a parameter used for encoding processing for converting the input data into the encoded feature vector, a parameter used for the decoding processing, and a parameter used to derive the quantization accuracy based on the objective function.

4. The encoding and decoding device according to claim 2,
wherein the binarization unit deletes the binary data out of a range of the quantization accuracy from the encoded data, and
wherein the extraction and shaping unit complements the binary data deleted from the encoded data with a predetermined value based on the quantization accuracy in the shaped decoded data.

5. The encoding and decoding device according to claim 2, wherein the extraction and shaping unit generates the shaped decoded data by acquiring binary data within the range of the quantization accuracy from the extracted binary data and shaping a format of the binary data within the range of the quantization accuracy.

6. An encoding and decoding method executed by an encoding and decoding device, the method comprising:
an encoding step of converting input data into an encoded feature vector;
a quantization accuracy derivation step of deriving quantization accuracy for each encoded feature which is an element of the encoded feature vector in accordance with an encoded code amount,
a quantization step of generating a quantized encoded feature vector with a size of a quantized code amount which targets the encoded code amount by executing quantization processing on the encoded feature vector based on the quantization accuracy;
a binarization step of generating encoded data by performing binarization processing on the quantized encoded feature vector; and
a decoding step of executing decoding processing on predetermined data in accordance with the encoded data.

7. A non-transitory computer-readable medium having computer-executable instructions that, upon execution of the instructions by a processor of a computer, cause the computer to function as the encoding and decoding device according to claim 1.
